(19) United States
(12) Patent Application Publication
(10) Pub. No.: US 2016/0161566 A1
(43) Pub. Date: Jun. 9, 2016

(54) METHOD AND SYSTEM FOR ONLINE ESTIMATING INTERNAL RESISTANCE OF BATTERY

(71) Applicant: Industrial Technology Research Institute, Hsin-Chu (TW)

(72) Inventors: BING-REN CHEN, New Taipei City (TW); SHIH-HSIANG CHIEN, Yilan County (TW)

(21) Appl. No.: 14/883,023

(22) Filed: Oct. 14, 2015

(30) Foreign Application Priority Data
Dec. 5, 2014 (TW) 103142411

(51) Int. Cl. G01R 31/36; B60L 11/18

(52) U.S. Cl. CPC G01R 31/3662; B60L 11/1864; B60L 11/1861; B60L 11/1811; B60L 11/1848; G01R 31/3648

(57) ABSTRACT

A method and a system are provided for online estimating internal resistance of battery. The system includes: a high-voltage battery pack for providing high-voltage DC power, a voltage detection unit for detecting the total voltage of the high-voltage battery pack, a current detection unit for detecting the total current of the high-voltage battery pack, a secondary battery for providing low-voltage DC power, a DC/DC conversion unit for conversing the high voltage DC power to a low voltage DC power and transferring the latter to the secondary battery, a drive unit for driving the vehicle, an on-board charging unit for charging high-voltage battery pack, and a control unit. The control unit controls the system to measure information of a constant current and a corresponded voltage difference of the battery pack at the moment the constant current happened before and after, and then to calculate internal resistance of the battery pack.

### CROSS REFERENCE TO RELATED APPLICATION

This application also claims priority to Taiwan Patent Application No. 103142411 filed in the Taiwan Patent Office on Dec. 5, 2014, the entire content of which is incorporated herein by reference.

### TECHNICAL FIELD

The present disclosure relates to a method and system for online estimating internal resistance of battery, and more particularly, to a method and system capable of measuring information of a constant current and a corresponded voltage difference of the battery pack at the moment the constant current happened before and after so as to be used in a calculation for estimating internal resistance of a battery pack.

### BACKGROUND

Conventionally, the online methods for estimating internal resistance of battery can only measure the internal resistance of a battery precisely after the current load of a loading end of the battery had been partially relieved. Especially for those power supply devices that are composed of a plurality of serially connected battery packs, as the operation of such power supply devices must be stopped before any internal resistance measurement can be performed on each battery pack inside the power supply devices. In a condition when a measurement process is performed before off-loading, the inspection signals of the measurement process will be fed to the loading ends of the battery packs that are to be measured, causing the accuracy of the measurement to be adversely affected. Consequently, such condition can be a serious issue for hybrid electric vehicles, since the hybrid electric vehicles must be parked and stationed for the battery packs that are mounted on the hybrid electric vehicles to be unloaded so as to be ready for measuring internal resistance of the battery packs, which can be very time-consuming and costly in human labor. Furthermore, as the packs capacity will deteriorate with time and as the battery packs can only be unloaded for measurement occasionally, the actual state-of-charge of a battery pack may not be revealed in real time on a operating hybrid vehicle, and thus the driver of the hybrid electric vehicle can be misleading to make erroneous judgment.

Generally, battery capacity compensation parameters are provided by information related to internal resistance of battery in many battery capacity estimation processes, which are performed conventionally using a test platform composed of a plurality of battery packs in multiple and repeated experimental tests until an lookup table of internal resistance compensation can be built. Moreover, it is noted that the resistance of battery packs that are made of the same material can be different when they are operating under different working environments and conditions, which can be a problem affecting the accuracy of battery capacity estimation.

### SUMMARY

In an embodiment, the present disclosure provides a system for online estimating internal resistance of battery, which is suitable for electric vehicles and hybrid electric vehicles. The system comprises: a high-voltage battery pack, for providing high-voltage DC power to a vehicle; a voltage detection unit, for detecting the total voltage of the high-voltage battery pack; a current detection unit, for detecting the total current of the high-voltage battery pack; a DC/DC conversion unit, for conversing the high voltage DC power to a low voltage DC power; a drive unit, for driving the vehicle; an on-board charging unit, for charging high-voltage battery pack; and a control unit, for receiving signals from the voltage detection unit and the current detection unit to be used for calculating an internal resistance of the high-voltage battery pack.

In an embodiment, the present disclosure provides a method for online estimating internal resistance of battery, which is suitable for electric vehicles and hybrid electric vehicles. Operationally, the method controls a system to measure information of a constant current and a corresponded voltage difference of a high-voltage battery pack at the moment the constant current happened before and after within a specific period of time, so as to be used for calculating an internal resistance of the high-voltage battery pack.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing a system for online estimating internal resistance of battery according to an embodiment of the present disclosure.

FIG. 2 is a flow chart depicting steps performed in a method for online estimating internal resistance of battery according to an embodiment of the present disclosure that is operating under judgment mode A.

FIG. 3 and FIG. 4 are flow charts depicting steps that are performed in the method for online estimating internal resistance of battery according to an embodiment of the present disclosure that is operating under different judgment modes.

FIG. 5 is a flow chart depicting steps performed in a method for online estimating internal resistance of battery according to another embodiment the present disclosure.

FIG. 6 is diagram showing the time-varying relationship between voltage and current in a driving vehicle of the present disclosure.

FIG. 7 is diagram showing the time-varying relationship between voltage and current in a charging vehicle of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

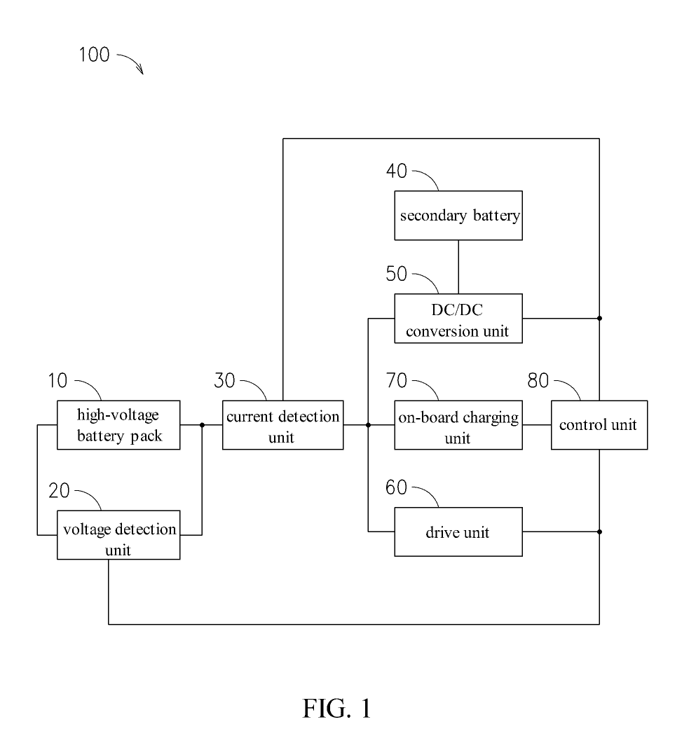

Please refer to FIG. 1, which is a schematic diagram showing a system for online estimating internal resistance of battery according to an embodiment of the present disclosure. In this embodiment, the system for online estimating internal resistance of battery 100 includes: a high-voltage battery pack 10, a voltage detection unit 20, a current detection unit 30, a secondary battery 40, a DC/DC conversion unit 50, a drive unit 60, an on-board charging unit 70 and a control unit 80.

The system for online estimating internal resistance of battery 100 is suitable for electric vehicles, hybrid electric vehicles or plug-in hybrid electric vehicles. Operationally, the high-voltage battery pack 10 is used for providing high-voltage DC power for driving a vehicle; the voltage detection unit 20 is used for detecting the total voltage of the high-voltage battery pack 10; The current detection unit 30 is used for detecting the total current of the high-voltage battery pack 10; the secondary battery 40 is used for providing low-voltage DC power to the vehicle; the DC/DC conversion unit 50 is used for conversing the high voltage DC power to a low voltage DC power and transferring the low voltage DC power to the secondary battery 40; the drive unit 60 can be an electric device composed of motors or electric generators, that it can be is an electric device composed of motors coupling to an engine for those hybrid electric vehicles or plug-in hybrid electric vehicles; the on-board charging unit 70 is used for charging the high-voltage battery pack 10 by the use of an external power source; and the control unit 80 is connecting to the voltage detection unit 20, the current detection unit 30, the DC/DC conversion unit 50, the drive unit 60 and the on-board charging unit 70 for calculating an internal resistance of the high-voltage battery pack 10 according to the total current of the voltage detection unit 20 and the total current of the current detection unit 30.

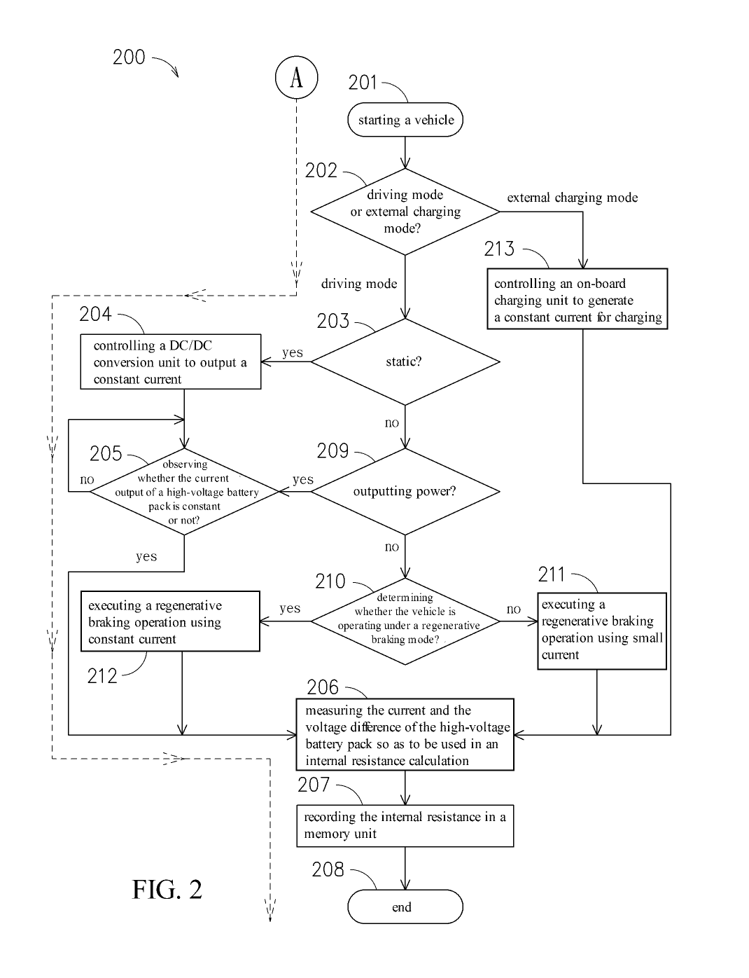

Please refer to FIG. 2, which is a flow chart depicting steps performed in a method for online estimating internal resistance of battery according to an embodiment of the present disclosure that is operating under judgment mode A. The method 200 of FIG. 2 is designed to operate under various judgment modes, whereas in FIG. 2, the method is applied to the system of FIG. 1 and is operating under the judgment mode A that is executed sequentially following the dotted line shown in FIG. 2. Accordingly, the judgment mode A starts from step 201. At step 201, a vehicle is ignited, and then the flow proceeds to step 202. At step 202, an evaluation is made for determining whether the vehicle is operating under a driving mode or an external charging mode, and if the vehicle is operating under the driving mode, the flow proceeds to step 203, otherwise when the vehicle is operating under the external charging mode, the flow proceeds to step 213. At step 203, an evaluation is made for determining whether the vehicle is static or not, and if so, the flow proceeds to step 204, otherwise, the flow proceeds to step 209. At step 204 when the vehicle is static, the control unit 80 is enabled to control the DC/DC conversion unit 50 to direct the high-voltage battery pack 10 to output a constant current in a stable manner, and then the flow proceeds to step 205. At step 205, when the vehicle is igniting but is not moving as it is parked temporarily or is stopped by traffic light, an observation is executed for ensuring the high-voltage battery pack 10 to output the constant current in a stable manner, if so, the flow proceeds to step 206, otherwise, the flow proceeds to the observation of step 205 again. The so-called stable current output represents the output current must be maintained at a constant with a specific range of error, and in an embodiment, there can be a 5% range of error. Moreover, it is noted that in the beginning of a current output, the output current may not be stable until after a period of time, e.g. 1 min, and thus it is necessary to execute the aforesaid observation step 215 until the variation of the output current is maintained within the specific range of error, whereas this is when the flow can proceeds to step 206. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow while the internal resistance that is stored in the memory unit is provided and used in a posterior calculation of calculating the capacity of the high-voltage battery pack 10.

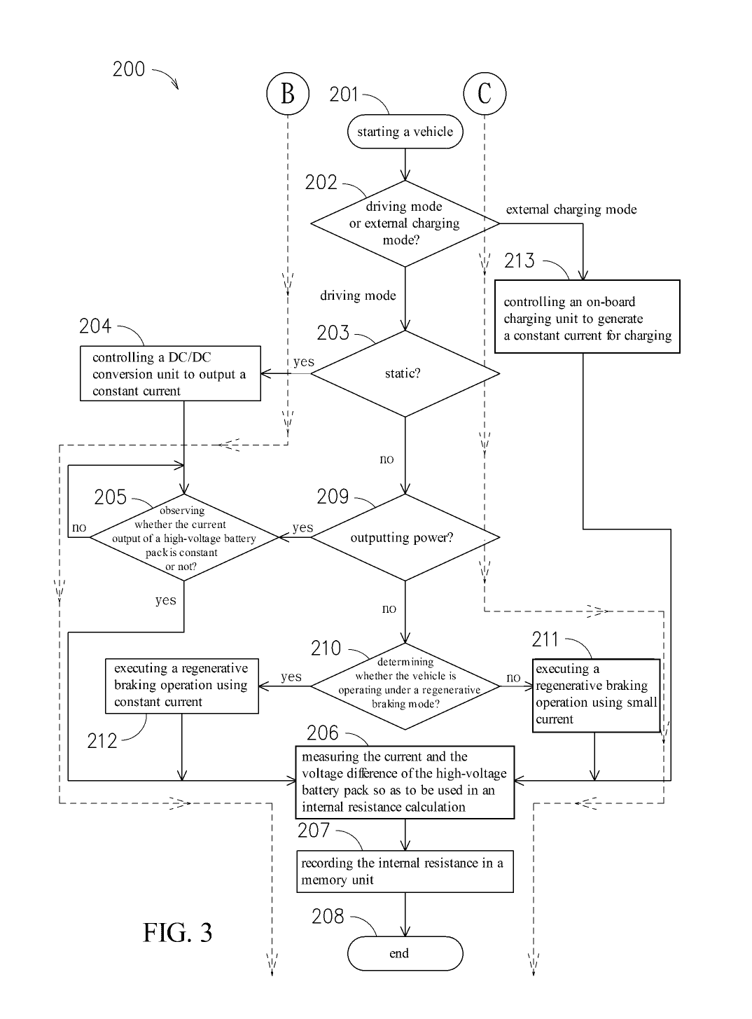

Please refer to FIG. 3, which is a flow chart depicting steps that are performed in the method for online estimating internal resistance of battery according to an embodiment of the present disclosure that is operating under judgment modes B and C. In FIG. 3, the method 200 is applied to the system of FIG. 1 and is operating under the judgment mode B and C that are executed sequentially following the dotted line shown in FIG. 3. The difference between FIG. 2 and FIG. 3 is that: the steps being executed in the judgment modes B and C are different from those in the judgment mode A.

Accordingly, the judgment mode B is executed following the left dotted line and also starts from step 201. At step 201, a vehicle is started, and then the flow proceeds to step 202. At step 202, an evaluation is made for determining whether the vehicle is operating under a driving mode or an external charging mode, and if the vehicle is operating under the driving mode, the flow proceeds to step 203, otherwise when the vehicle is operating under the external charging mode, the flow proceeds to step 213. At step 203, an evaluation is made for determining whether the vehicle is static or not, and if so, the flow proceeds to step 204, otherwise when the vehicle is static, the flow proceeds to step 209. At step 209, an evaluation is made for determining whether the vehicle is outputting power, and if so, the flow proceeds to step 205, otherwise, the flow proceeds to step 210. In an embodiment, the determining of whether the vehicle is outputting power can be made according to whether there is current being fed into the drive unit 60. At step 205, when the vehicle is outputting power, the control unit 80 is enable to observe the high-voltage battery pack 10 for determining whether the output current is constant within a period of time, if so, the flow proceeds to step 206, otherwise, the flow proceeds back to the observation of step 205 again until the variation of the output current is maintained within the specific range of error. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow.

On the other hand, the judgment mode C is executed following the right dotted line but also starts from step 201. At step 201, a vehicle is started, and then the flow proceeds to step 202. At step 202, an evaluation is made for determining whether the vehicle is operating under a driving mode or an external charging mode, and if the vehicle is operating under the driving mode, the flow proceeds to step 203, otherwise when the vehicle is operating under the external charging mode, the flow proceeds to step 213. At step 209, an evaluation is made for determining whether the vehicle is outputting power, and if so, the flow proceeds to step 205, otherwise when the vehicle is not outputting power, e.g. the acceleration pedal is released, the flow proceeds to step 210. At step 210, an evaluation is made for determining whether the vehicle is operating under a regenerative braking mode, and if so, the flow proceeds to step 212, otherwise, the flow proceeds to step 211. It is noted that the regenerative braking mode is unique for electric vehicles, which enables the electric vehicle to convert the moving momentum of the vehicle into electricity. Such regenerative braking can be executed in two ways that either it can be enabled at the moment when the driver steps on the brake of the vehicle, or it can be enabled when the vehicle is not braking, but by converting the drive unit 60 of the vehicle into an electric generator while allowing the control unit 80 to control the drive unit 60 to generate electricity for charging the high-voltage battery pack 10 in step 211. The step 206 is executed after the step 211. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow.

Please refer to FIG. 4, which is a flow chart depicting steps that are performed in the method for online estimating internal resistance of battery according to an embodiment of the present disclosure that is operating under judgment modes D and E. In FIG. 4, the method 200 is applied to the system of FIG. 1 and is operating under the judgment mode D and E that are executed sequentially following the dotted line shown in FIG. 4. The difference between FIG. 2 and FIG. 4 is that: the steps being executed in the judgment modes D and E are different from those in the judgment mode A.

Accordingly, the judgment mode D is executed following the left dotted line and also starts from step 201. At step 201, a vehicle is started, and then the flow proceeds to step 202. At step 202, an evaluation is made for determining whether the vehicle is operating under a driving mode or an external charging mode, and if the vehicle is operating under the driving mode, the flow proceeds to step 203, otherwise when the vehicle is operating under the external charging mode, the flow proceeds to step 213. At step 203, an evaluation is made for determining whether the vehicle is static or not, and if so, the flow proceeds to step 204, otherwise when the vehicle is static, the flow proceeds to step 209. At step 209, an evaluation is made for determining whether the vehicle is outputting power, and if so, the flow proceeds to step 205, otherwise, the flow proceeds to step 210. At step 210, an evaluation is made for determining whether the vehicle is operating under a regenerative braking mode, and if so, the flow proceeds to step 212, otherwise, the flow proceeds to step 211. At step 212, a regenerative braking operation is enabled and controlled by the control unit 80 to generate a constant current, and then the flow proceeds to step 206. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow.

On the other hand, the judgment mode E is executed following the right dotted line but also starts from step 201. At step 201, a vehicle is started, and then the flow proceeds to step 202. At step 202, an evaluation is made for determining whether the vehicle is operating under a driving mode or an external charging mode, and if the vehicle is operating under the driving mode, the flow proceeds to step 203, otherwise when the vehicle is operating under the external charging mode, the flow proceeds to step 213. At step 213, the control unit 80 directs the on-board charging unit 70 to generate a constant current for charging the high-voltage battery pack 10, and then the flow proceeds to step 206. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow.

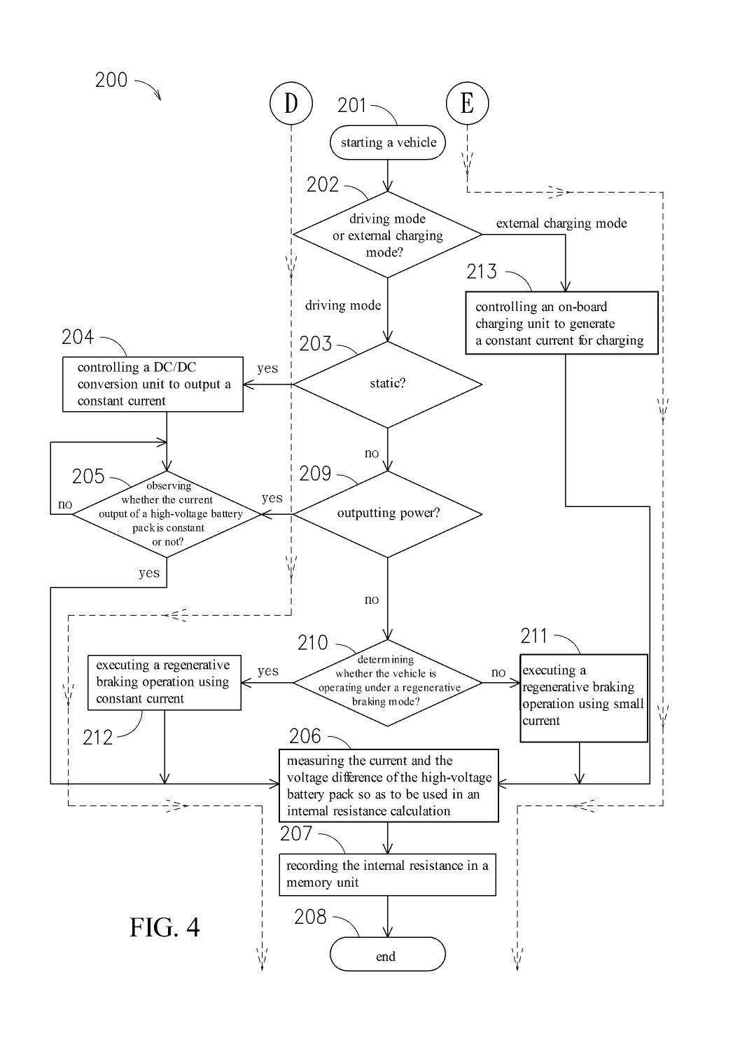

The judgment modes A˜E that are shown in the flow charts depicted in FIG. 2˜FIG. 4 can be performed only when the drive unit 60 is an electric device composed of motors or generators, i.e. it is useful only for electric vehicles. However, as it is indicated in the aforesaid description that the drive unit 60 can also be an electric device composed of engines and motors, i.e. the present disclosure can also be applied to hybrid electric vehicles or plug-in hybrid electric vehicles. Thus, for adapting the method of the present disclosure to hybrid electric vehicles or plug-in hybrid electric vehicles, the method 200A with an additional step 214 is provided, as shown in FIG. 5. Please refer to FIG. 5, which is a flow chart depicting steps performed in a method for online estimating internal resistance of battery according to an embodiment of the present disclosure that is operating under judgment mode F.

Accordingly, the judgment mode F is executed following the left dotted line and also starts from step 201. At step 201, a vehicle is started, and then the flow proceeds to step 214. At step 214, an evaluation is made for determining whether the engine of the vehicle is ignited or not, and if so, the flow proceeds to step 215, otherwise, the flow proceeds to step 202 so as to be executed in a way similar to those described in judgment modes A˜E. At step 215, the engine controls the drive unit 60 to generate a constant current for charging the high-voltage battery pack 10, and then the flow proceeds to step 206. At step 206, the control unit 80 is enabled to obtain the constant current and a corresponded voltage difference so as to be used for calculating an internal resistance of the high-voltage battery pack 10, and then the flow proceeds to step 207. At step 207, the internal resistance is stored in a memory unit, and then the flow proceeds to step 208 for ending the flow.

In the present disclosure, the internal resistance R_{DC} of the high-voltage battery pack is calculated using the following DC load measurement formula:

$${R}_{DC} = \frac{Δ v}{i} ( Ω ) \qquad ( 1 )$$

wherein, Δv is the voltage difference of the battery pack before and after the charging/discharging;
   i is the current of the battery pack.

All the internal resistances of different judgment modes A˜F can be calculated and obtained using the above formula (1). To sum up, the method for online estimating internal resistance of battery that is provided in the present disclosure adopts a constant-current control strategy and a DC load measurement means that can be suitable for electric vehicles and hybrid electric vehicles, and more particularly, is capable of measuring information of a constant current and a corresponded voltage difference of the battery pack at the moment the constant current happened before and after so as to be used in a calculation for estimating internal resistance of a battery pack. In addition, the real-time/online used in the title of the present disclosure indicates that the estimation of the internal resistance can be performed instantly and automatically right after the ignition of the vehicle without offloading. It is noted that the control unit not only can be used for controlling the detection upon the high-voltage battery pack, but also can be e used for controlling the detection upon the secondary battery. As for the times of detection, it can either be determined by the control unit, or by enabling the detection to be executed once when the capacity varied by 10%.

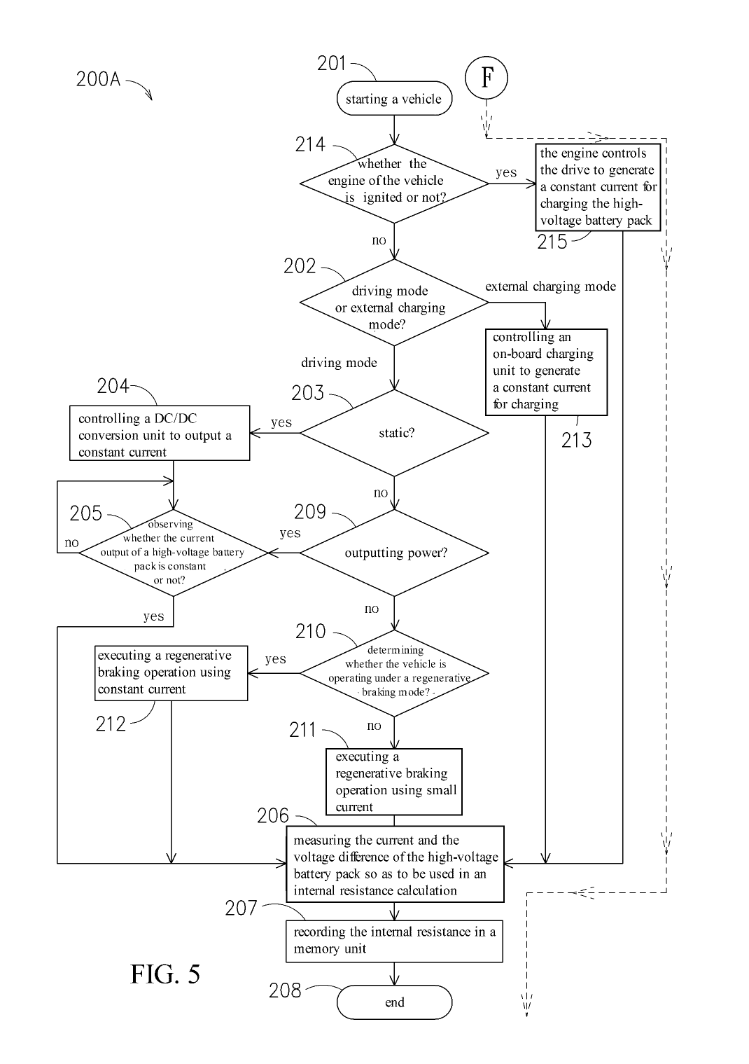

Please refer to FIG. 6, which is diagram showing the time-varying relationship between voltage and current in a vehicle operating in the judgment mode B of FIG. 3 at the moment when the vehicle is moving and outputting power. As shown in FIG. 6, the curve L61 represents voltage, the curve L62 represents current, and the curve L63 represents speed of the vehicle. As the vehicle in FIG. 6 is started (step 201) and being determined to be operating under the driving mode (step 202), and also is outputting power (step 209), thereafter the step 205 is enabled to execute an observation for ensuring the high-voltage battery pack 10 to output the constant current in a stable manner. As shown in FIG. 6, in the duration between 9˜11 seconds, the current output of the vehicle becomes constant, so that this is when the calculation of internal resistance can be performed; then at 11 seconds, the power is 0 and thus the current output suddenly dropped to 0, causing the voltage of the high-voltage battery pack 10 to boost so that a voltage difference Δv can be recorded. Consequently, by the use of the recorded voltage difference Δv and the constant current i, the internal resistance can be calculated. In this embodiment shown in FIG. 6, the internal resistance is 133 mΩ.

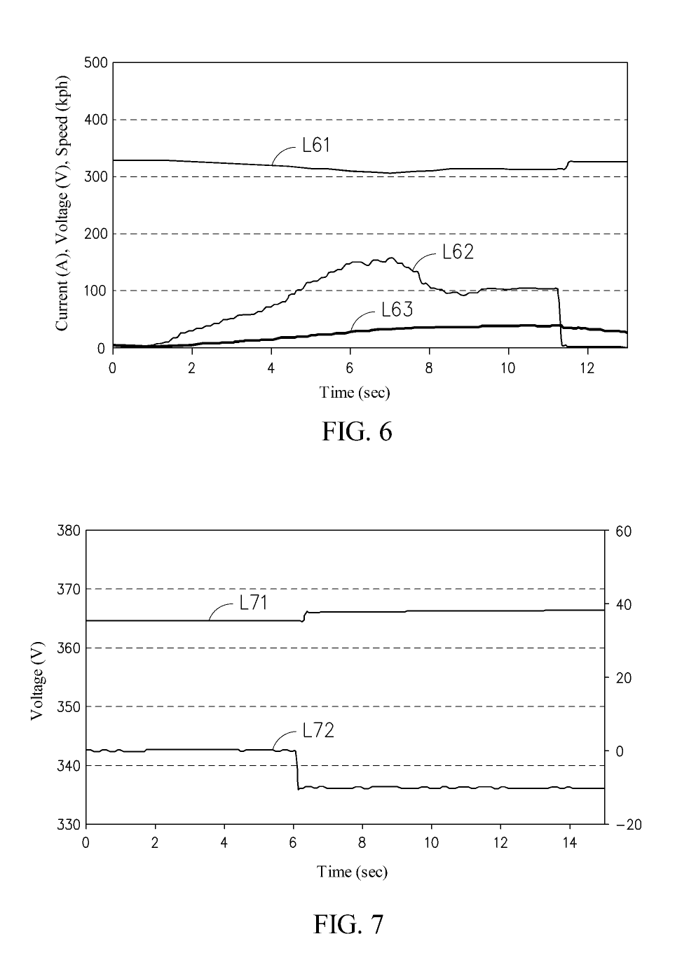

Please refer to FIG. 7, which is diagram showing the time-varying relationship between voltage and current in a vehicle operating in the judgment mode E of FIG. 4 at the moment when the vehicle is in the external charging mode. As shown in FIG. 7, the curve L71 represents voltage, and the curve L72 represents current. As the vehicle in FIG. 7 is started (step 201) and being determined to be operating under the external charging mode (step 202), the control unit 80 is enabled to charge the on-board charging unit 70 using a constant current. As shown in FIG. 7, before the charging starts, the current is 0, and after 6 seconds, the vehicle is able to generate a constant current of 10 A for charging, so that this is when the calculation of internal resistance can be performed. Similarly, due to the instant current change, there is also a boost to voltage of the high-voltage battery pack 10 so that a voltage difference Δv can be recorded. Consequently, by the use of the recorded voltage difference Δv and the constant current i, the internal resistance can be calculated. In this embodiment shown in FIG. 6, the internal resistance is 141 mΩ.

To sum up, the present disclosure provides a system and method for online estimating internal resistance of battery, which is capable of utilizing the charging characteristics of various power sources, including currents being generated by the moving of a vehicle, currents generated in a regenerative braking process, currents from a DC/DC conversion unit and currents from an on-board charging unit, and thereby, is able to control a control unit to measure information of a constant current and a corresponded voltage difference of the battery pack to be used in a calculation for obtaining an internal resistance of the battery pack. The system and method of the present disclosure can be adapted for measuring internal resistances of the high-voltage battery packs for hybrid electric vehicles, plug-in hybrid electric vehicles and electric vehicles. Consequently, the voltage and current of such high-voltage battery packs are measured directly, so that the corresponding internal resistances can be obtained in a calculation without any estimation. In addition, the information of the internal resistance not only can be used for compensating a battery capacity estimation, but also can be used for determining the aging of a battery pack. Moreover, since the system and method of the present disclosure can be performed in an online manner for allowing the information of internal resistance to be obtained and updated at any time during the operation of a vehicle, drivers of electric vehicles, hybrid vehicles and plug-in hybrid electric vehicles can obtained precise battery information, and thereby not only the range anxiety of the drivers can be relieved, but also the risk of aging battery can be prevented. Nevertheless, the method of the present disclosure is able to calculate the internal resistance of a battery pack without having to add any additional power sources or circuits to the system, so that the method of the present disclosure can be performed without being influenced by any environmental factors, such as temperature, climate, road condition, etc., and also can be performed during charging or discharging. Thus, the internal resistance of a battery pack can be obtained almost at no cost, and also is obtained easily without suffering the problems of other conventional methods.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A system for online estimating internal resistance of battery, suitable for electric vehicles and hybrid electric vehicles, comprising:
a high-voltage battery pack configured to provide high-voltage DC power to a vehicle;
a voltage detection unit configured to detect the total voltage of the high-voltage battery pack;
a current detection unit configured to detect the total current of the high-voltage battery pack;
a DC/DC conversion unit configured to converse the high voltage DC power to a low voltage DC power;
a drive unit configured to drive the vehicle;
an on-board charging unit configured to charge high-voltage battery pack; and
a control unit, connected to the voltage detection unit, the current detection unit, the DC/DC conversion unit, the drive unit and the on-board charging unit, is configured to calculate an internal resistance of the high-voltage battery pack according to the total current and a difference relating to the total voltage.

2. The system of claim 1, wherein the drive unit is an electric device composed of motors or electric generators; and the control unit is enabled to control the total current and total voltage that are inputted into or outputted from the drive unit while calculating an internal resistance of the high-voltage battery pack according to the total current and a difference relating to the total voltage.

3. The system of claim 1, wherein the drive unit is an electric device composed of engines and motors; and the control unit is enabled to control the total current and total voltage that are inputted into or outputted from the drive unit while calculating an internal resistance of the high-voltage battery pack according to the total current and a difference relating to the total voltage.

4. The system of claim 1, wherein the difference relating to the total voltage is substantially a voltage difference when the total current is a constant current and at the moment the constant current happened before and after within a specific period of time.

5. A method for online estimating internal resistance of battery, suitable for electric vehicles and hybrid electric vehicles while each of the vehicle is configured with at least one high-voltage battery pack, comprising the steps of: controlling a system to measure information of a constant current and a corresponded voltage difference of the at least one high-voltage battery pack of the vehicle at the moment the constant current happened before and after within a specific period of time, so as to be used for calculating an internal resistance of the high-voltage battery pack.

6. The method of claim 5, wherein in a condition when the vehicle is enabled to operate in a driving mode while the vehicle is static, the high-voltage battery pack is controlled to output a constant current in a stable manner, while obtaining the constant current and a corresponded voltage difference so as to be used for calculating the internal resistance of the high-voltage battery pack.

7. The method of claim 5, wherein in a condition when the vehicle is enabled to operate in a driving mode while the vehicle is not static and is outputting power, an evaluation is made for determining whether the current outputted from the high-voltage battery pack is a constant current within the specific period of time, and if so, obtaining the constant current and a corresponded voltage difference so as to be used for calculating the internal resistance of the high-voltage battery pack.

8. The method of claim 5, wherein in a condition when the vehicle is enabled to operate in a driving mode while the vehicle is not static, is not outputting power and is not braking, the high-voltage battery pack is enabled to be charged by a constant current in a small current power generation operation, while obtaining the constant current and a corresponded voltage difference so as to be used for calculating the internal resistance of the high-voltage battery pack.

9. The method of claim 5, wherein in a condition when the vehicle is enabled to operate in a driving mode while the vehicle is not static, is not outputting power and is braking, a regenerative braking operation is enabled to generate a constant current, while obtaining the constant current and a corresponded voltage difference so as to be used for calculating the internal resistance of the high-voltage battery pack.

10. The method of claim 5, wherein in a condition when the vehicle is enabled to operate in an external charging mode, an operation is enabled to generate a constant current for charging the high-voltage battery pack, while obtaining the constant current and a corresponded voltage difference so as to be used for calculating the internal resistance of the high-voltage battery pack.

11. The method of claim 5, wherein in a condition when the engine of the vehicle is operating, an operation is enabled to generate a constant current for charging the high-voltage battery pack, while obtaining the constant current and a corresponded voltage difference so as to be used for calculating the internal resistance of the high-voltage battery pack.
